(19) United States
(12) Patent Application Publication
(10) Pub. No.: US 2025/0104744 A1
(43) Pub. Date: Mar. 27, 2025

(54) SEMICONDUCTOR MODULE

(71) Applicant: Mitsubishi Electric Corporation, Tokyo (JP)

(72) Inventors: Nobuo HASHIMOTO, Fukuoka-Shi (JP); Wataru HAYASHI, Fukuoka-Shi (JP)

(73) Assignee: Mitsubishi Electric Corporation, Tokyo (JP)

(21) Appl. No.: 18/827,635

(22) Filed: Sep. 6, 2024

(30) Foreign Application Priority Data
Sep. 22, 2023 (JP) 2023-158425

(51) Int. Cl. G11C 7/10; G11C 7/22

(52) U.S. Cl. CPC G11C 7/1036; G11C 7/1096; G11C 7/222

(57) ABSTRACT

A semiconductor module according to the present disclosure comprises complementarily operating first and second switching elements, a high potential side drive circuit including a first driver capable of adjusting an output to a first gate, and a low potential side drive circuit including a second driver capable of adjusting an output to a second gate. The high potential side drive circuit includes a first level shift unit to provide an output to the first driver, a shift register, a low voltage side set value holding unit, a write signal generation unit, a second level shift unit to level-shift information held in the low voltage side set value holding unit to a high potential in response to a write signal, a high voltage side set value holding unit, and a decoder to render the first driver's current outputting capability according to recording of the high voltage side set value holding unit.

### CROSS REFERENCE TO RELATED APPLICATIONS

This nonprovisional application is based on Japanese Patent Application No. 2023-158425 filed on Sep. 22, 2023 with the Japan Patent Office, the entire contents of which are hereby incorporated by reference.

### BACKGROUND OF THE INVENTION

### Field of the Invention

The present disclosure relates to a semiconductor module, and more specifically to a semiconductor module having incorporated therein a power transistor and a drive circuit to drive the power transistor.

### Description of the Background Art

A known semiconductor module has a micro processing unit (MPU) incorporated therein and having a function to generate a pulse width modulation (PWM) signal to internally generate the PWM signal in response to a signal received from an external controller to control a switching device.

In order to be able to change the semiconductor module's operation characteristics, it is necessary to perform communication between the external controller and an internal controller, and externally receive data for the change and also receive a trigger signal that defines a timing for the change, and accordingly, a terminal is required therefor and the module cannot be miniaturized.

In this respect, Japanese Patent Application Laying-Open No. 2020-205702 discloses a semiconductor module capable of changing operation characteristics.

### SUMMARY OF THE INVENTION

In the configuration indicated in Japanese Patent Application Laying-Open No. 2020-205702, there are a period of time for which a high voltage region in a drive device that drives complementarily driven power transistors has an abruptly varying voltage (i.e., a dV/dt period of time), and a negative potential period of time attributed to an undershoot. This period has a problem as a voltage level conversion (or a level shift circuit) that signals a set value to set a driving capability cannot do so and the driving capability is not set to a normal value.

The present disclosure overcomes the above issue and contemplates a semiconductor module capable of normally setting a driving capability.

One aspect of the present disclosure comprises: first and second switching elements connected in series between a first potential and a second potential lower than the first potential and operating in a complementary manner; a high potential side drive circuit including a first driver connected to a first gate of the first switching element and capable of adjusting an output to the first gate; and a low potential side drive circuit including a second driver connected to a second gate of the second switching element and capable of adjusting an output to the second gate, wherein the high potential side drive circuit includes: terminals to receive a drive signal, a data signal, a clock signal, and an enable signal, respectively, that are a data communication signal transmitted from an external controller; a first level shift unit to level-shift the drive signal to a high potential and output the level-shifted drive signal to the first driver; a shift register composed of a plurality of cascaded flip-flops, a data signal being recorded in the flip-flops in response to the clock signal and the enable signal, whenever the data signal is recorded in the flip-flops, the data having been recorded in the flip-flops being shifted to adjacent flip-flops; a low voltage side set value holding unit operative in response to the enable signal to extract and record contents recorded in the plurality of flip-flops of the shift register; a write signal generation unit to generate a write signal based on the drive signal and the enable signal; a second level shift unit operative in response to the write signal to level-shift information held in the low voltage side set value holding unit to a high potential; a high voltage side set value holding unit connected via the second level shift unit to record information identical to the information recorded in the low voltage side set value holding unit; and a decoder to render a current outputting capability of the first driver variable according to the recording of the high voltage side set value holding unit.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a diagram for generally illustrating a configuration of a semiconductor module according to a first embodiment.

FIG. 2 is a diagram for illustrating a circuit configuration of a first level shift unit 10 according to the first embodiment.

FIG. 3 is a diagram for illustrating a configuration of a driver 30 and a shift register unit 38 according to the first embodiment.

FIG. 4 is a diagram for illustrating a configuration of a high voltage side set value holding unit 16 and a second level shift unit 18 according to the first embodiment.

FIG. 5 is a diagram for illustrating setting information held by a controller (MCU) 2 according to the first embodiment.

FIG. 6 is timing plots for an output of a write signal TM1 according to the first embodiment.

FIG. 7 is other timing plots for the output of write signal TM1 according to the first embodiment.

FIG. 8 is a diagram for generally illustrating a configuration of a semiconductor module according to a second embodiment.

FIG. 9 is timing plots for an output of write signal TM1 according to the second embodiment.

FIG. 10 is a diagram for generally illustrating a configuration of a semiconductor module according to a third embodiment.

FIG. 11 is a diagram for generally illustrating a configuration of a semiconductor module according to a fourth embodiment.

FIG. 12 is a diagram for illustrating a configuration of a high voltage side set value holding unit 16A and a second level shift unit 18A according to the fourth embodiment.

FIG. 13 is a diagram for generally illustrating a configuration of a semiconductor module according to a fifth embodiment.

FIG. 14 is a diagram for illustrating a configuration of a high voltage side set value holding unit 16B, a second level shift unit 18B, and a low voltage side shift register unit 21 according to the fifth embodiment.

FIG. 15 is timing plots for an output of write signal TM1 according to the fifth embodiment.

FIG. 16 is other timing plots for the output of write signal TM1 according to the fifth embodiment.

FIG. 17 is a diagram for generally illustrating a configuration of a semiconductor module according to a sixth embodiment.

### DESCRIPTION OF THE PREFERRED EMBODIMENTS

Hereinafter, embodiments of the present disclosure will be described in detail with reference to the accompanying drawings. In the following, identical or equivalent components in the figures are identically denoted and will not be described redundantly in principle.

### First Embodiment

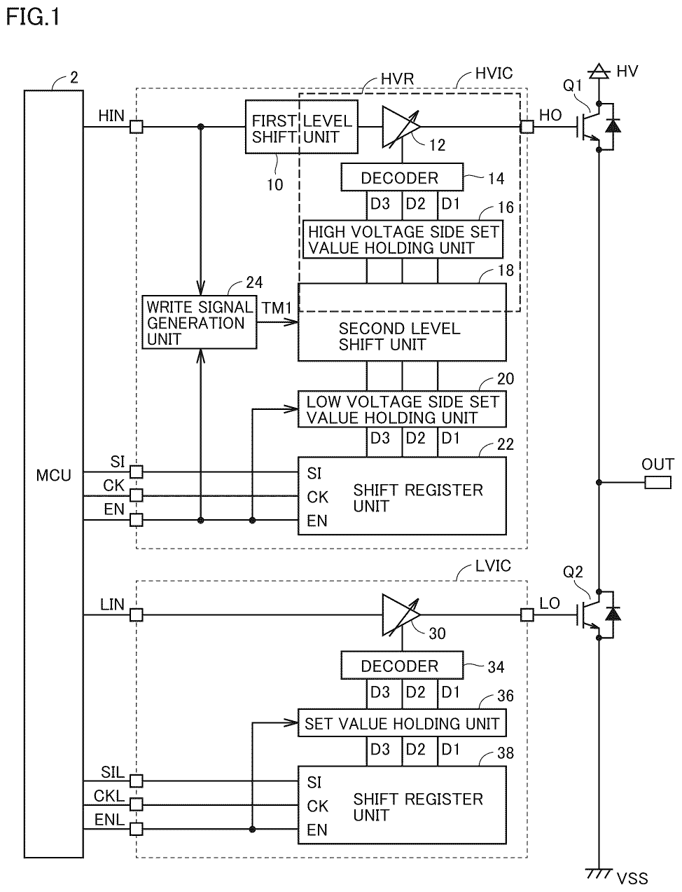

FIG. 1 is a diagram for generally illustrating a configuration of a semiconductor module according to a first embodiment. Referring to FIG. 1, the semiconductor module comprises power transistors (switching elements) Q1 and Q2, and a drive circuit to drive gates of power transistors Q1 and Q2. Power transistor Q1 is provided between a high potential HV and an output node OUT. Power transistor Q2 is provided between output node OUT and a ground potential VSS. The drive circuit includes a high side output capability variable gate device HVIC (a high potential side drive circuit), and a low side output capability variable gate device LVIC (a low potential side drive circuit). High side output capability variable gate device HVIC is provided to correspond to the gate of power transistor Q1. Low side output capability variable gate device LVIC is provided to correspond to the gate of power transistor Q2. Power transistors Q1 and Q2 are operated complementarily by gate-driving by high side output capability variable gate device HVIC and low side output capability variable gate device LVIC. Output node OUT is connected to a motor or the like as a load, for example.

Controller (MCU) 2 outputs a data communication signal to high side output capability variable gate device HVIC and low side output capability variable gate device LVIC to drive power transistors Q1 and Q2. High side output capability variable gate device HVIC and low side output capability variable gate device LVIC drive power transistors Q1 and Q2, respectively, in accordance with the data communication signal received from controller 2. High side output capability variable gate device HVIC has input terminals HIN, SI, CK, and EN. High side output capability variable gate device HVIC also has an output terminal HO. Input terminal HIN receives a high side drive signal from controller 2. Input terminal SI receives a data signal from controller 2. Input terminal CK receives a clock signal from controller 2. Input terminal EN receives an enable signal from controller 2. Output terminal HO is connected to the gate of power transistor Q1.

High side output capability variable gate device HVIC includes a first level shift unit 10 to level-shift the high side drive signal to a high potential, a write signal generation unit 24, a shift register unit 22, a low voltage side set value holding unit 20, a second level shift unit 18, a high voltage side set value holding unit 16, a decoder 14, and a driver 12.

Shift register unit 22 is composed of a plurality of cascaded DT flip-flops. Shift register unit 22 operates in accordance with the data signal, the clock signal and the enable signal to record an input data signal and move (or shift) the data signal to an adjacent DT flip-flop. In this example, a 3-bit data signal (D1 to D3) is held in shift register unit 22 and output to low voltage side set value holding unit 20.

Low voltage side set value holding unit 20 holds information that is held in shift register unit 22 in response to the enable signal. Specifically, low voltage side set value holding unit 20 holds the information that is held in shift register unit 22 in response to the enable signal falling or rising.

Second level shift unit 18 level-shifts the data signal that is the 3-bit information held in low voltage side set value holding unit 20 to a high potential in accordance with a write signal TM1 generated by write signal generation unit 24.

High voltage side set value holding unit 16 holds information of the 3-bit data signal (D1 to D3) level-shifted by second level shift unit 18.

Decoder 14 performs decoding based on the data signal (D1 to D3) held in high voltage side set value holding unit 16 and outputs the decoding to driver 12.

In this example, a high voltage region HVR is indicated, and a part of first and second level shift units 10 and 18, driver 12, decoder 14, and high voltage side set value holding unit 16 are provided in this region.

Write signal generation unit 24 outputs write signal TM1 based on the high side drive signal and the enable signal.

Low side output capability variable gate device LVIC has input terminals LIN, SIL, CKL, and ENL. Low side output capability variable gate device LVIC also has an output terminal LO. Input terminal LIN receives a low side drive signal from controller 2. Input terminal SIL receives a data signal from controller 2. Input terminal CKL receives a clock signal from controller 2. Input terminal ENL receives an enable signal from controller 2. Output terminal LO is connected to the gate of power transistor Q2.

Low side output capability variable gate device LVIC includes a shift register unit 38, a set value holding unit 36, a decoder 34, and a driver 30.

Shift register unit 38 is composed of a plurality of cascaded DT flip-flops. Shift register unit 38 operates in accordance with the data signal, the clock signal and the enable signal to record an input data signal and move (or shift) the data signal to an adjacent DT flip-flop. In this example, a 3-bit data signal (D1 to D3) is held in shift register unit 38 and output to set value holding unit 36.

Set value holding unit 36 holds information that is held in shift register unit 38 in response to the enable signal. Set value holding unit 36 holds the information that is held in shift register unit 38 in response to the enable signal falling or rising.

Decoder 34 performs decoding based on the data signal (D1 to D3) held by set value holding unit 36 and outputs the decoding to driver 30.

In this example, a description will be given of a case in which write signal TM1 generated based on the high side drive signal and the enable signal by write signal generation unit 24 is used to transmit information recorded in low voltage side set value holding unit 20 to high voltage side set value holding unit 16 to perform communication while avoiding a period of time for which high voltage region HVR has an abruptly varying voltage and second level shift unit 18 cannot signal (i.e., a dV/dt period of time), and a negative voltage period of time.

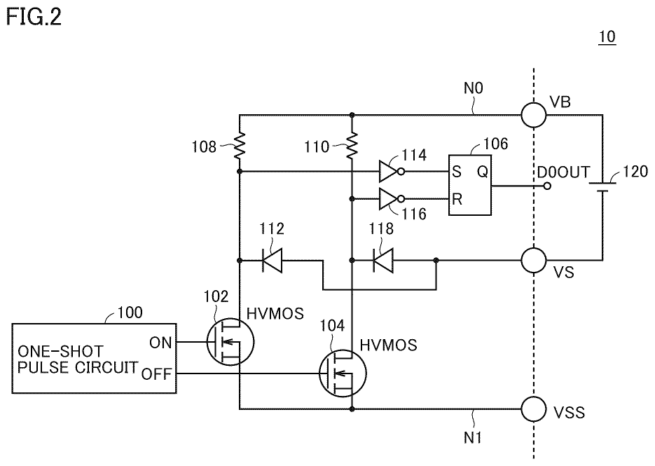

FIG. 2 is a diagram for illustrating a circuit configuration of first level shift unit 10 according to the first embodiment. Referring to FIG. 2, first level shift unit 10 includes an on/off one-shot pulse circuit 100, high breakdown voltage MOS transistors 102 and 104, an SR flip-flop 106, inverters 114 and 116, diodes 112 and 118, and resistive elements 108 and 110.

On/off one-shot pulse circuit 100 outputs a one-shot pulse at a time of turning on/off (or when an input signal rises/falls). On/off one-shot pulse circuit 100 outputs a one-shot pulse to the gate of high breakdown voltage MOS transistor 102 at the time of turning on (or when the input signal rises). On/off one-shot pulse circuit 100 outputs a one-shot pulse to the gate of high breakdown voltage MOS transistor 104 at the time of turning off (or when the input signal falls). A node N0 is connected to a terminal VB. A floating power supply 120 is connected between terminal VB and a terminal VS. Terminal VSS, connected to a ground potential GND, is connected to a node N1. High breakdown voltage MOS transistors 102 and 104 are connected in parallel between node N0 and node N1. Resistive element 108 is provided between the source side of high breakdown voltage MOS transistor 102 and node N0. Resistive element 110 is provided between the source side of high breakdown voltage MOS transistor 104 and node N0. Diode 112 has an anode side connected to terminal VS, which will have an intermediate potential, and a cathode side connected to a connection node between resistive element 108 and high breakdown voltage MOS transistor 102. Diode 118 has an anode side connected to terminal VS that will have the intermediate potential, and a cathode side connected to a connection node between resistive element 110 and high breakdown voltage MOS transistor 104. Diodes 112 and 118 clamp a cathode voltage to falling from the voltage of terminal VS to the VF voltage of the diodes so as to avoid exceeding the breakdown voltages of inverters 114 and 116 and resistive elements 108 and 110.

When high breakdown voltage MOS transistor 102 is turned off, the potential of the connection node between resistive element 108 and high breakdown voltage MOS transistor 102 is set to a high potential. Accordingly, inverter 114 outputs a signal set to the “L” level. Similarly, when high breakdown voltage MOS transistor 104 is turned off, the potential of the connection node between resistive element 110 and high breakdown voltage MOS transistor 104 is set to a high potential. Accordingly, inverter 116 outputs a signal set to the “L” level.

When high breakdown voltage MOS transistor 102 is driven (or turned on), the potential of the connection node between resistive element 108 and high breakdown voltage MOS transistor 102 falls. Accordingly, inverter 114 outputs a signal set to the “H” level. Similarly, when high breakdown voltage MOS transistor 104 is driven (or turned on), the potential of the connection node between resistive element 110 and high breakdown voltage MOS transistor 104 falls. Accordingly, inverter 116 outputs a signal set to the “H” level.

On/off one-shot pulse circuit 100 outputs a one-shot pulse at the time of turning on (or when the input signal rises). This turns on high breakdown voltage MOS transistor 102. This pulls the connection node with resistive element 108 to the “L” level, and inverter 114 outputs the “H” level. That is, the RS flip-flop sets “1”. On/off one-shot pulse circuit 100 outputs a one-shot pulse at the time of turning off (or when the input signal falls). This turns on high breakdown voltage MOS transistor 104. This pulls the connection node with resistive element 110 to the “L” level, and inverter 116 outputs the “H” level. That is, the RS flip-flop is reset to “0”.

With this configuration, a drive signal input to on/off one-shot pulse circuit 100 is level-shifted to a high potential and held in RS flip-flop 106. RS flip-flop 106 outputs a held data signal from a terminal D0OUT.

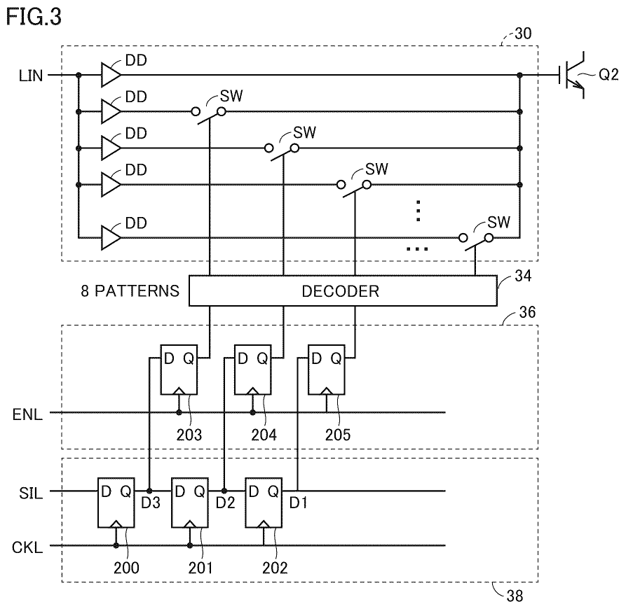

FIG. 3 is a diagram for illustrating a configuration of driver 30 and shift register unit 38 according to the first embodiment. Referring to FIG. 3, shift register unit 38 has a plurality of flip-flops (DT-FFs) 200 to 202 cascaded to configure a shift register. A data signal input from input terminal SIL is input to a D input of forefront flip-flop 200, and a Q output of forefront flip-flop 200 is input to a D input of flip-flop 201 of a subsequent stage. A Q output of flip-flop 201 of the subsequent stage is input to a D input of flip-flop 202 of a subsequent stage. Flip-flops 200 to 202 have their Q outputs output to set value holding unit 36 as data D3, D2, and D1.

A clock signal input from input terminal CKL is input to clock inputs of all flip-flops 200 to 202. A data signal input in response to the clock input is transmitted to a flip-flop of a subsequent stage and held in the flip-flop of the subsequent stage.

Set value holding unit 36 includes a plurality of flip-flops (DT-FFs) 203 to 205. Flip-flop 203 receives at a D input an output of flip-flop 200, or data D3. Flip-flop 204 receives at a D input an output of flip-flop 201, or data D2. Flip-flop 205 receives at a D input an output of flip-flop 202, or data D1. An enable signal input from input terminal ENL is input to clock inputs of all flip-flops 203 to 205.

Thus, flip-flops 203 to 205 of set value holding unit 36 hold the Q outputs of flip-flops 200 to 202, or data D3, D2 and D1, in response to the enable signal received from input terminal ENL, and output the data to decoder 34. Set value holding unit 36 holds 3-bit information (D1 to D3). Decoder 34 performs decoding based on the 3-bit information into an 8-pattern signal.

Driver 30 includes a plurality of drivers DDs connected in parallel to the gate of power transistor Q2. The plurality of drivers DDs except for one driver DD are all connected to the gate of power transistor Q2 via a switch SW, and switch SW is switched on/off to control connection to and disconnection from the gate of power transistor Q2. Switch SW is switched on/off as controlled by a set value, which is the Q outputs of flip-flops 200 to 202. Decoder 34 performs decoding based on the 3-bit information in set value holding unit 36 into the 8-pattern signal to control switching on/off switch SW.

Driver 30 has switch SW switched on in accordance with the 8-pattern signal output from decoder 34. When the number of switches SW of driver 30 is increased, the number of drivers DDs driving power transistor Q2 can be increased. This can increase the driving capability of driver 30. In this way, the driving capability can be set variably depending on the set value. While FIG. 3 illustrates the configuration of driver 30 of low side output capability variable gate device LVIC, the configuration of shift register unit 22 and driver 12 of high side output capability variable gate device HVIC is similarly discussed.

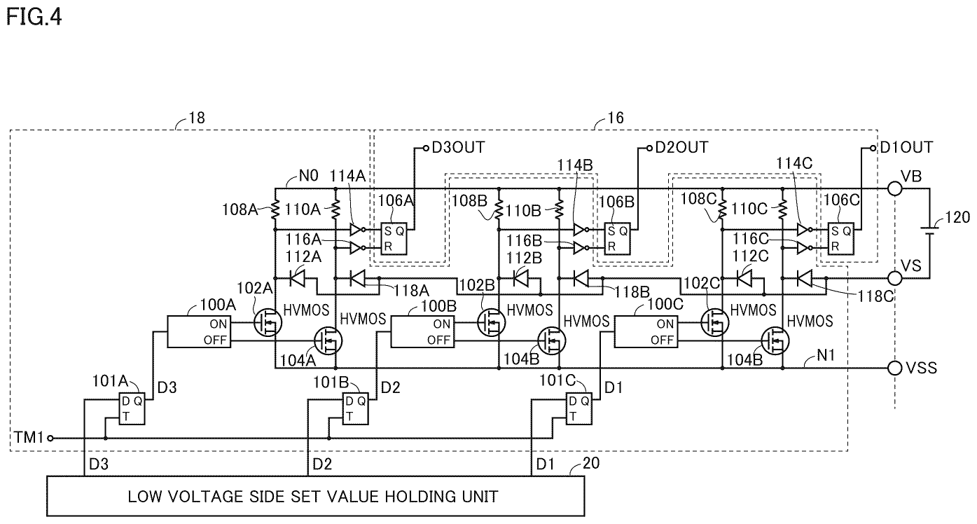

FIG. 4 is a diagram for illustrating a configuration of high voltage side set value holding unit 16 and second level shift unit 18 according to the first embodiment. Referring to FIG. 4, high voltage side set value holding unit 16 includes a plurality of flip-flops 106A to 106C.

Second level shift unit 18 includes a plurality of flip-flops (DT-FFs) 101A-101C, on/off one-shot pulse circuits 100A-100C, high breakdown voltage MOS transistors 102A-102C and 104A-104C, SR flip-flops 106A-106C, inverters 114A-114C and 116A-116C, diodes 112A-112C and 118A-118C, and resistive elements 108A-108C and 110A-110C.

Flip-flop 101A is triggered by write signal TM1 to hold data D3 held in low voltage side set value holding unit 20. Flip-flop 101B is triggered by write signal TM1 to hold data D2 held in low voltage side set value holding unit 20. Flip-flop 101C is triggered by write signal TM1 to hold data D1 held in low voltage side set value holding unit 20.

On/off one-shot pulse circuit 100A outputs a one-shot pulse when data D3 is turned on/off (or when an input signal rises/falls). On/off one-shot pulse circuit 100A outputs a one-shot pulse to the gate of high breakdown voltage MOS transistor 102A when the data is turned on (or when the input signal rises). On/off one-shot pulse circuit 100A outputs a one-shot pulse to the gate of high breakdown voltage MOS transistor 104A when the data is turned off (or when the input signal falls). Node N0 is connected to terminal VB. Floating power supply 120 is connected between terminal VB and terminal VS. Terminal VSS connected to ground potential GND is connected to node N1. High breakdown voltage MOS transistors 102A and 104A are connected in parallel between node N0 and node N1. Resistive element 108A is provided between the source side of high breakdown voltage MOS transistor 102A and node N0. Resistive element 110A is provided between the source side of high breakdown voltage MOS transistor 104A and node N0. Diode 112A has an anode side connected to terminal VS, which will have an intermediate potential, and a cathode side connected to a connection node between resistive element 108A and high breakdown voltage MOS transistor 102A. Diode 118A has an anode side connected to terminal VS that will have the intermediate potential, and a cathode side connected to a connection node between resistive element 110A and high breakdown voltage MOS transistor 104A.

When high breakdown voltage MOS transistor 102A is turned off, the potential of the connection node between resistive element 108A and high breakdown voltage MOS transistor 102A is set to a high potential. Accordingly, inverter 114A outputs a signal set to the “L” level. Similarly, when high breakdown voltage MOS transistor 104A is turned off, the potential of the connection node between resistive element 110A and high breakdown voltage MOS transistor 104A is set to a high potential. Accordingly, inverter 116A outputs a signal set to the “L” level.

When high breakdown voltage MOS transistor 102A is driven (or turned on), the potential of the connection node between resistive element 108A and high breakdown voltage MOS transistor 102A falls. Accordingly, inverter 114A outputs a signal set to the “H” level. Similarly, when high breakdown voltage MOS transistor 104A is driven (or turned on), the potential of the connection node between resistive element 110A and high breakdown voltage MOS transistor 104A falls. Accordingly, inverter 116A outputs a signal set to the “H” level.

On/off one-shot pulse circuit 100A outputs a one-shot pulse when data D3 is turned on (or when the input signal rises). This turns on high breakdown voltage MOS transistor 102A. This pulls the connection node with resistive element 108A to the “L” level, and inverter 114A outputs the “H” level. That is, the RS flip-flop sets “1”. On/off one-shot pulse circuit 100A outputs a one-shot pulse when data D3 is turned off (or when the input signal falls). This turns on high breakdown voltage MOS transistor 104A. This pulls the connection node with resistive element 110A to the “L” level, and inverter 116A outputs the “H” level. That is, RS flip-flop 106A is reset to “0”.

With this configuration, data D3 input to on/off one-shot pulse circuit 100A is level-shifted to a high potential and held in RS flip-flop 106A. RS flip-flop 106A outputs a held data signal from a terminal D3OUT.

On/off one-shot pulse circuit 100B outputs a one-shot pulse when data D2 is turned on/off (or when an input signal rises/falls). On/off one-shot pulse circuit 100B outputs a one-shot pulse to the gate of high breakdown voltage MOS transistor 102B when the data is turned on (or when the input signal rises). On/off one-shot pulse circuit 100B outputs a one-shot pulse to the gate of high breakdown voltage MOS transistor 104B when the data is turned off (or when the input signal falls). Node N0 is connected to terminal VB. Floating power supply 120 is connected between terminal VB and terminal VS. Terminal VSS connected to ground potential GND is connected to node N1. High breakdown voltage MOS transistors 102B and 104B are connected in parallel between node N0 and node N1. Resistive element 108B is provided between the source side of high breakdown voltage MOS transistor 102B and node N0. Resistive element 110B is provided between the source side of high breakdown voltage MOS transistor 104B and node N0. Diode 112B has an anode side connected to terminal VS that will have the intermediate potential, and a cathode side connected to a connection node between resistive element 108B and high breakdown voltage MOS transistor 102B. Diode 118B has an anode side connected to terminal VS that will have the intermediate potential, and a cathode side connected to a connection node between resistive element 110B and high breakdown voltage MOS transistor 104B.

When high breakdown voltage MOS transistor 102B is turned off, the potential of the connection node between resistive element 108B and high breakdown voltage MOS transistor 102B is set to a high potential. Accordingly, inverter 114B outputs a signal set to the “L” level. Similarly, when high breakdown voltage MOS transistor 104B is turned off, the potential of the connection node between resistive element 110B and high breakdown voltage MOS transistor 104B is set to a high potential. Accordingly, inverter 116B outputs a signal set to the “L” level.

When high breakdown voltage MOS transistor 102B is driven (or turned on), the potential of the connection node between resistive element 108B and high breakdown voltage MOS transistor 102B falls. Accordingly, inverter 114B outputs a signal set to the “H” level. Similarly, when high breakdown voltage MOS transistor 104B is driven (or turned on), the potential of the connection node between resistive element 110B and high breakdown voltage MOS transistor 104B falls. Accordingly, inverter 116B outputs a signal set to the “H” level.

On/off one-shot pulse circuit 100B outputs a one-shot pulse when data D2 is turned on (or when the input signal rises). This turns on high breakdown voltage MOS transistor 102B. This pulls the connection node with resistive element 108B to the “L” level, and inverter 114B outputs the “H” level. That is, the RS flip-flop sets “1”. On/off one-shot pulse circuit 100B outputs a one-shot pulse when data D2 is turned off (or when the input signal falls). This turns on high breakdown voltage MOS transistor 104B. This pulls the connection node with resistive element 110B to the “L” level, and inverter 116B outputs the “H” level. That is, the RS flip-flop is reset to “0”.

With this configuration, data D2 input to on/off one-shot pulse circuit 100B is level-shifted to a high potential and held in RS flip-flop 106B. RS flip-flop 106B outputs a held data signal from a terminal D2OUT.

On/off one-shot pulse circuit 100C outputs a one-shot pulse when data D1 is turned on/off (or when an input signal rises/falls). On/off one-shot pulse circuit 100C outputs a one-shot pulse to the gate of high breakdown voltage MOS transistor 102C when the data is turned on (or when the input signal rises). On/off one-shot pulse circuit 100C outputs a one-shot pulse to the gate of high breakdown voltage MOS transistor 104C when the data is turned off (or when the input signal falls). Node N0 is connected to terminal VB. Floating power supply 120 is connected between terminal VB and terminal VS. Terminal VSS connected to ground potential GND is connected to node N1. High breakdown voltage MOS transistors 102C and 104C are connected in parallel between node N0 and node N1. Resistive element 108C is provided between the source side of high breakdown voltage MOS transistor 102C and node N0. Resistive element 110C is provided between the source side of high breakdown voltage MOS transistor 104C and node N0. Diode 112C has an anode side connected to terminal VS that will have the intermediate potential, and a cathode side connected to a connection node between resistive element 108C and high breakdown voltage MOS transistor 102C. Diode 118C has an anode side connected to terminal VS that will have the intermediate potential, and a cathode side connected to a connection node between resistive element 110C and high breakdown voltage MOS transistor 104C.

When high breakdown voltage MOS transistor 102C is turned off, the potential of the connection node between resistive element 108C and high breakdown voltage MOS transistor 102C is set to a high potential. Accordingly, inverter 114C outputs a signal set to the “L” level. Similarly, when high breakdown voltage MOS transistor 104C is turned off, the potential of the connection node between resistive element 110C and high breakdown voltage MOS transistor 104C is set to a high potential. Accordingly, inverter 116C outputs a signal set to the “L” level.

When high breakdown voltage MOS transistor 102C is driven (or turned on), the potential of the connection node between resistive element 108C and high breakdown voltage MOS transistor 102C falls. Accordingly, inverter 114C outputs a signal set to the “H” level. Similarly, when high breakdown voltage MOS transistor 104C is driven (or turned on), the potential of the connection node between resistive element 110C and high breakdown voltage MOS transistor 104C falls. Accordingly, inverter 116C outputs a signal set to the “H” level.

On/off one-shot pulse circuit 100C outputs a one-shot pulse when data D1 is turned on (or when the input signal rises). This turns on high breakdown voltage MOS transistor 102C. This pulls the connection node with resistive element 108C to the “L” level, and inverter 114C outputs the “H” level. That is, the RS flip-flop sets “1”. On/off one-shot pulse circuit 100C outputs a one-shot pulse when data D1 is turned off (or when the input signal falls). This turns on high breakdown voltage MOS transistor 104C. This pulls the connection node with resistive element 110C to the “L” level, and inverter 116C outputs the “H” level. That is, the RS flip-flop is reset to “0”.

With this configuration, data D1 input to on/off one-shot pulse circuit 100C is level-shifted to a high potential and held in RS flip-flop 106C. RS flip-flop 106C outputs a held data signal from a terminal D1OUT.

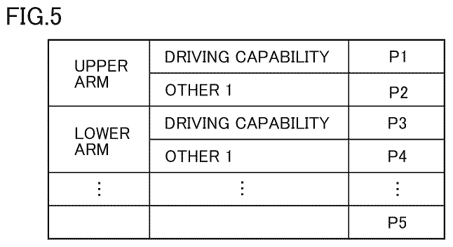

FIG. 5 is a diagram for illustrating setting information held by controller (MCU) 2 according to the first embodiment. Referring to FIG. 5, a driving force table is provided in a memory of controller (MCU) 2. For example, a plurality of pieces of set value data defining a driving capability for the driver of high side output capability variable gate device HVIC (an upper gate) and that for the driver of low side output capability variable gate device LVIC (a lower gate) are stored.

In this example, data P1 and P2 for the driver on the side of an upper arm and data P3 and P4 for the driver on the side of a lower arm are stored as the set value data for the drivers' driving capabilities.

While in addition to the drivers' driving capabilities another capability is also specified, as indicated as “other 1” by way of example, the other capability is not identified in the present embodiment.

Controller 2 reads data using the driving force table, as necessary, and stores the data in shift register unit 22 of high side output capability variable gate device HVIC (or the upper gate) and shift register unit 38 of low side output capability variable gate device LVIC (or the lower gate).

This allows the driving capability of driver 12 and that of driver 30 to be variable.

As has been set forth above, there may be a period of time for which a high voltage region in a drive device that drives complementarily driven power transistors has an abruptly varying voltage (i.e., a dV/dt period of time), and a negative potential period of time attributed to an undershoot.

In this period, a voltage level conversion (or the level shift circuit) that signals a set value to set a driving capability cannot do so, and the driving capability is not set to a normal value.

Write signal generation unit 24 according to the first embodiment is operative in accordance with the high side drive signal to adjust a timing of outputting write signal TM1. The above problem is avoided by signaling in accordance with the timing of write signal TM1.

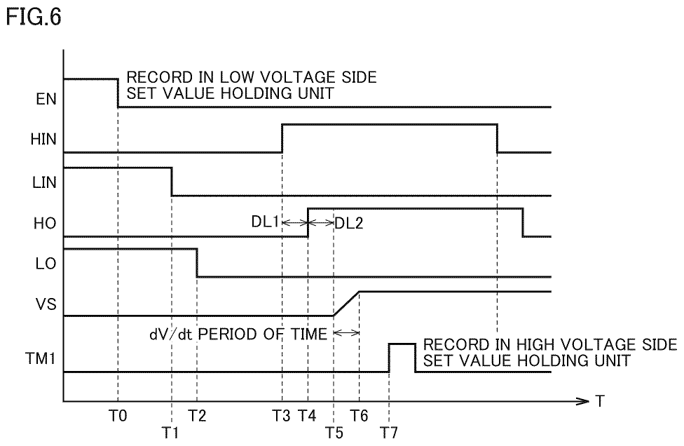

FIG. 6 is timing plots for an output of write signal TM1 according to the first embodiment. Referring to FIG. 6, at time T0, when the enable signal falls (or rises), contents recorded in the plurality of flip-flops of shift register unit 22 are extracted and recorded in low voltage side set value holding unit 20, and thereafter at time T1 the low side drive signal of input terminal LIN falls.

At time T2, output terminal LO outputs a gate signal of the “L” level and power transistor Q2 turns off.

At time T3, the high side drive signal of input terminal HIN rises complementarily. At time T4, output terminal HO outputs a gate signal of the “H” level and power transistor Q1 turns on.

Accordingly, for a period of time from time T5 to time T6, a connection node between power transistor Q1 and power transistor Q2 has a rising potential.

Accordingly, high voltage region HVR of high side output capability variable gate device HVIC has an abruptly varying voltage for a period of time (i.e., a dV/dt period of time). In this period, signaling cannot be performed in voltage level conversion (or the level shift circuit) and there is a possibility that setting cannot be normally performed.

Accordingly, in the first embodiment, write signal generation unit 24 raises write signal TM1 after the period of time having the abrupt variation, or at time T7.

Thus, the data signal (D1 to D3) held in low voltage side set value holding unit 20 is held in high voltage side set value holding unit 16 via second level shift unit 18. Decoder 14 converts the data signal into an 8-pattern signal, and thereafter the driving capability of driver 12 is changed.

After the high side drive signal from input terminal HIN rises, write signal generation unit 24 outputs write signal TM1 after a delay time DL1 until a gate signal rises from output terminal HO, a delay time DL2 until power transistor Q1 is turned on, and the period of time (dV/dt) for which high voltage region HVR varies in voltage as power transistor Q1 is turned on. This allows recording to be done in high voltage side set value holding unit 16 while avoiding a period of time for which voltage level conversion (or the level shift circuit) cannot signal. Write signal generation unit 24 outputs write signal TM1 after a predetermined period of time elapses after the high side drive signal from input terminal HIN rises. The predetermined period of time is set to be longer than a total of delay times DL1 and DL2 and the predetermined period of time (dV/dt) having the variation.

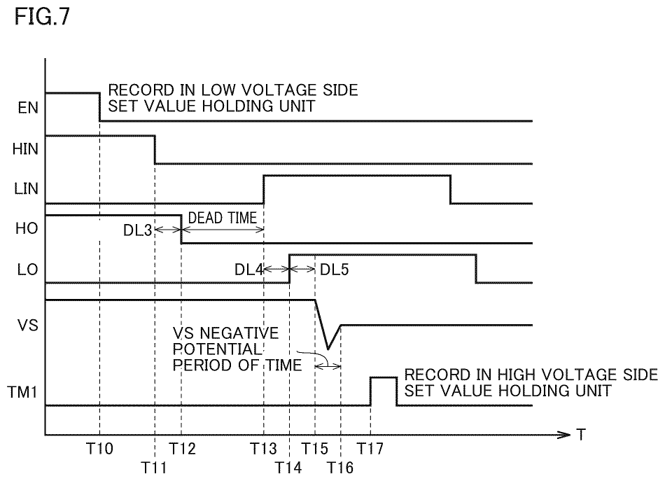

FIG. 7 is other timing plots for the output of write signal TM1 according to the first embodiment. Referring to FIG. 7, at time T0, when the enable signal falls (or rises), contents recorded in the plurality of flip-flops of shift register unit 22 are extracted and recorded in low voltage side set value holding unit 20, and thereafter at time T11 the high side drive signal of input terminal HIN falls.

At time T12, output terminal HO outputs a gate signal of the “L” level and power transistor Q1 turns off.

At time T13, the low side drive signal of input terminal LIN rises complementarily. At time T14, output terminal LO outputs a gate signal of the “H” level and power transistor Q2 turns on.

Accordingly, for a period of time from time T15 to time T16, the connection node between power transistor Q1 and power transistor Q2 has an abruptly falling potential. Accordingly, high voltage region HVR of high side output capability variable gate device HVIC has an abruptly varying voltage for a period of time (i.e., a VS negative potential period of time). In this period, high voltage region HVR has a negative voltage and therefore, signaling cannot be performed in voltage level conversion (or the level shift circuit), and there is a possibility that setting cannot be normally performed.

Accordingly, in the first embodiment, write signal generation unit 24 raises write signal TM1 after the period of time for which high voltage region HVR of high side output capability variable gate device HVIC has a negative voltage, or at time T17.

Thus, the data signal (D1 to D3) held in low voltage side set value holding unit 20 is held in high voltage side set value holding unit 16 via second level shift unit 18. Decoder 14 converts the data signal into the 8-pattern signal, and thereafter the driving capability of driver 12 is changed.

After the high side drive signal falls, write signal generation unit 24 outputs write signal TM1 after a delay time DL3 until a gate signal falls from output terminal HO, a dead time (DEAD TIME) set so that power transistors Q1 and Q2 are not turned on at the same time, a delay time DL4 after the low side drive signal rises until a gate signal rises from output terminal LO, a delay time DL5 until power transistor Q2 is turned on, and a period of time for which high voltage region HVR has a negative voltage as power transistor Q2 is turned on. This allows recording to be done in high voltage side set value holding unit 16 while avoiding a period of time for which voltage level conversion (or the level shift circuit) cannot signal. Write signal generation unit 24 outputs write signal TM1 after a predetermined period of time elapses after the high side drive signal from input terminal HIN falls. The predetermined period of time is set to be longer than a total of delay times DL3, DL4 and DL5, the dead time (DEAD TIME), and the VS negative potential period of time.

### Second Embodiment

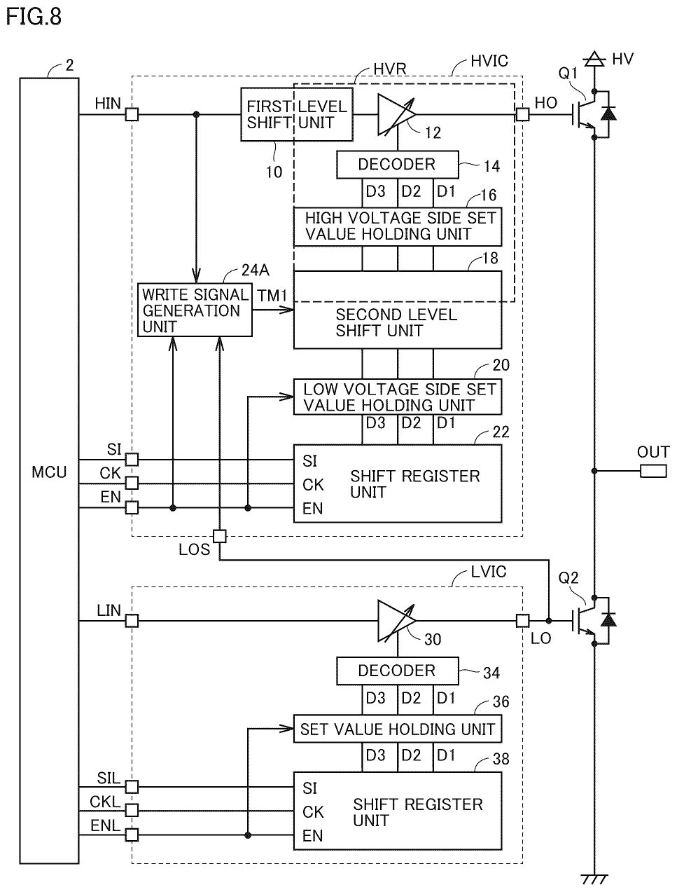

FIG. 8 is a diagram for generally illustrating a configuration of a semiconductor module according to a second embodiment. Referring to FIG. 8, the semiconductor module according to the second embodiment is different from the semiconductor module according to the first embodiment in that the signal of output terminal LO of low side output capability variable gate device LVIC (the low potential side drive circuit) is provided as an input for high side output capability variable gate device HVIC (the high potential side drive circuit). Specifically, high side output capability variable gate device HVIC is provided with an additional input terminal LOS. Input terminal LOS receives the signal of output terminal LO of low side output capability variable gate device LVIC (the low potential side drive circuit).

Further, write signal generation unit 24 is replaced with a write signal generation unit 24A. Write signal generation unit 24A outputs write signal TM1 based on the high side drive signal, the low side drive signal, and the enable signal.

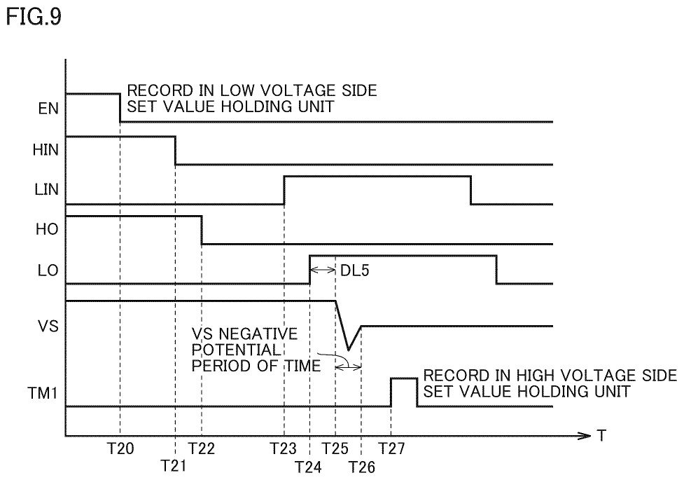

FIG. 9 is timing plots for an output of write signal TM1 according to the second embodiment. Referring to FIG. 9, at time T20, when the enable signal falls (or rises), contents recorded in the plurality of flip-flops of shift register unit 22 are extracted and recorded in low voltage side set value holding unit 20, and thereafter at time T21 the high side drive signal of input terminal HIN falls.

At time T22, output terminal HO outputs a gate signal of the “L” level and power transistor Q1 turns off.

At time T23, the low side drive signal of input terminal LIN rises complementarily. At time T24, output terminal LO outputs a gate signal of the “H” level and power transistor Q2 turns on.

Accordingly, for a period of time from time T25 to time T26, high voltage region HVR of high side output capability variable gate device HVIC has a negative voltage.

In this example, write signal generation unit 24A raises write signal TM1 after the period of time with the negative voltage, or at time T27.

Thus, the data signal (D1 to D3) held in low voltage side set value holding unit 20 is held in high voltage side set value holding unit 16A via second level shift unit 18A. Decoder 14 converts the data signal into the 8-pattern signal, and thereafter the driving capability of driver 12 is changed.

Write signal generation unit 24A outputs write signal TM1 after delay time DL5 since the gate signal from output terminal LO rises until power transistor Q2 is turned on and a period of time for which high voltage region HVR has a negative voltage as power transistor Q2 is turned on. This allows recording to be done in high voltage side set value holding unit 16 while avoiding a period of time for which voltage level conversion (or the level shift circuit) cannot signal. Write signal generation unit 24 outputs write signal TM1 after a predetermined period of time elapses after the low side drive signal from input terminal LOS rises. The predetermined period of time is set to be longer than a total of delay time DL5 and the VS negative potential period of time.

The rising of the high side drive signal is similar to that described with reference to FIG. 6.

The configuration according to the second embodiment allows recording to be done in high voltage side set value holding unit 16 while more accurately avoiding a period of time for which voltage level conversion (or the level shift circuit) cannot signal.

### Third Embodiment

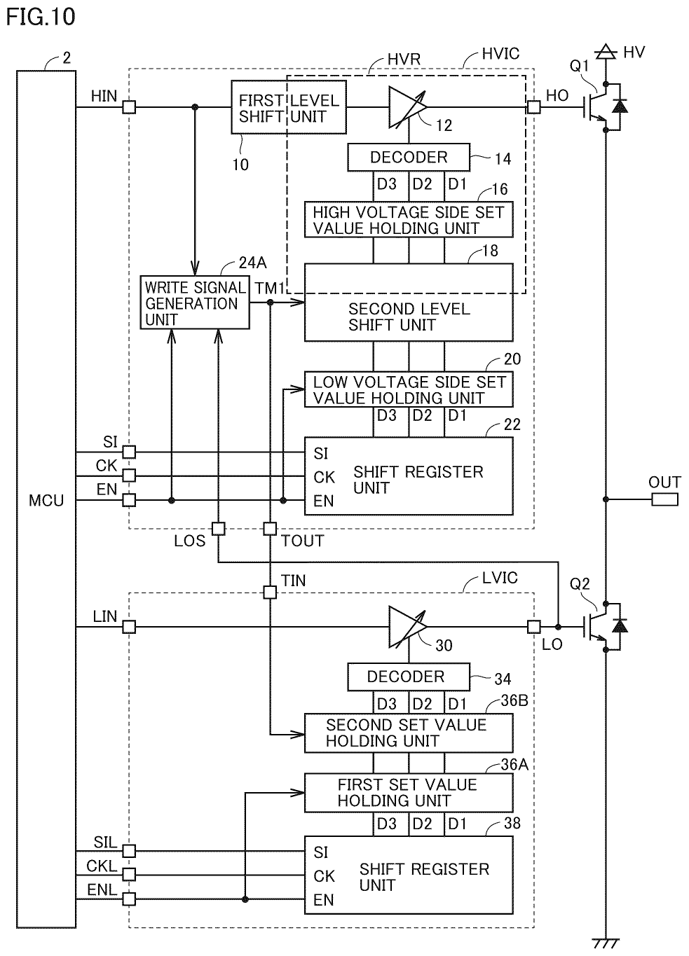

FIG. 10 is a diagram for generally illustrating a configuration of a semiconductor module according to a third embodiment. Referring to FIG. 10, the semiconductor module according to the third embodiment is different from the semiconductor module according to the second embodiment in that write signal TM1 of high side output capability variable gate device HVIC (the high potential side drive circuit) is provided as an input for low side output capability variable gate device LVIC (the low potential side drive circuit). Specifically, high side output capability variable gate device HVIC is provided with an additional output terminal TOUT. Further, low side output capability variable gate device LVIC is provided with an additional input terminal TIN. Input terminal TIN receives write signal TM1 via output terminal TOUT of high side output capability variable gate device HVIC (the high potential side drive circuit).

Low side output capability variable gate device LVIC has a set value holding unit in a two-stage configuration. Specifically, set value holding unit 36 is replaced with a first set value holding unit 36A and a second set value holding unit 36B.

First set value holding unit 36A is operative in response to an enable signal to hold the information held in shift register unit 38.

Second set value holding unit 36B is operative in response to write signal TM1 to further hold the information held in first set value holding unit 36A.

With this configuration, information of a set value of low side output capability variable gate device LVIC is updated in accordance with write signal TM1 at the same time as information of a set value of high side output capability variable gate device HVIC (the high potential side drive circuit) is updated.

In the configurations according to the first and second embodiments, only low side output capability variable gate device LVIC may have information of a set value updated, whereas the configuration according to the third embodiment allows the information of the set value to be updated in response to the same write signal TM1, and thus allows simultaneous adjustment of driving capabilities and hence an efficient change.

### Fourth Embodiment

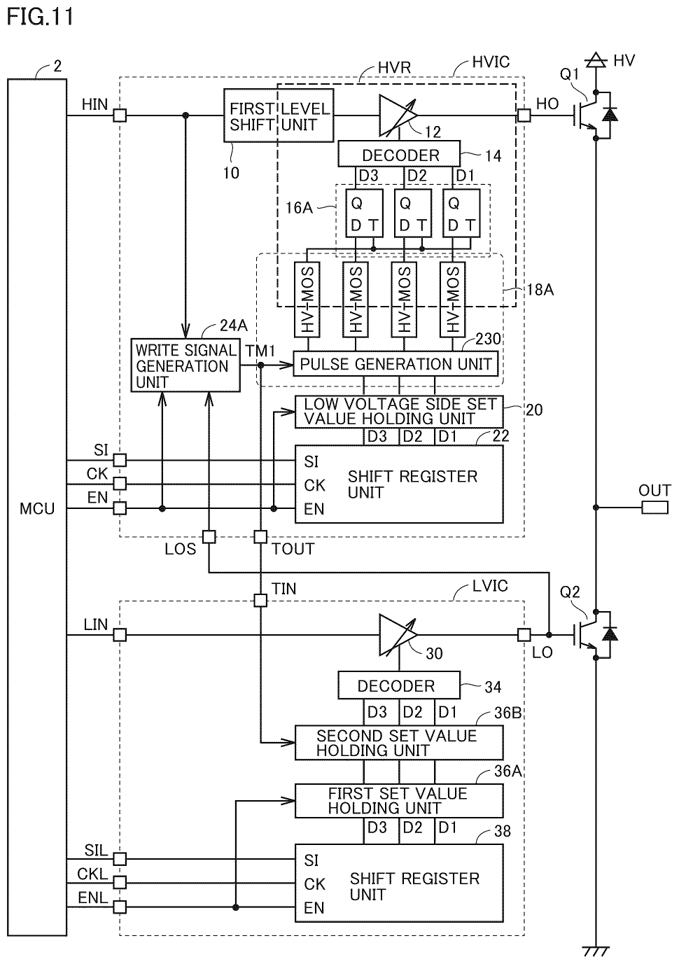

FIG. 11 is a diagram for generally illustrating a configuration of a semiconductor module according to a fourth embodiment. Referring to FIG. 11, the semiconductor module according to the fourth embodiment is different from the semiconductor module according to the third embodiment in that second level shift unit 18 is replaced with second level shift unit 18A. It is also different in that high voltage side set value holding unit 16 is replaced with high voltage side set value holding unit 16A.

Second level shift unit 18A is composed of a pulse generation unit 230 and a plurality of high breakdown voltage MOS transistors. In this example, four high breakdown voltage MOS transistors are included.

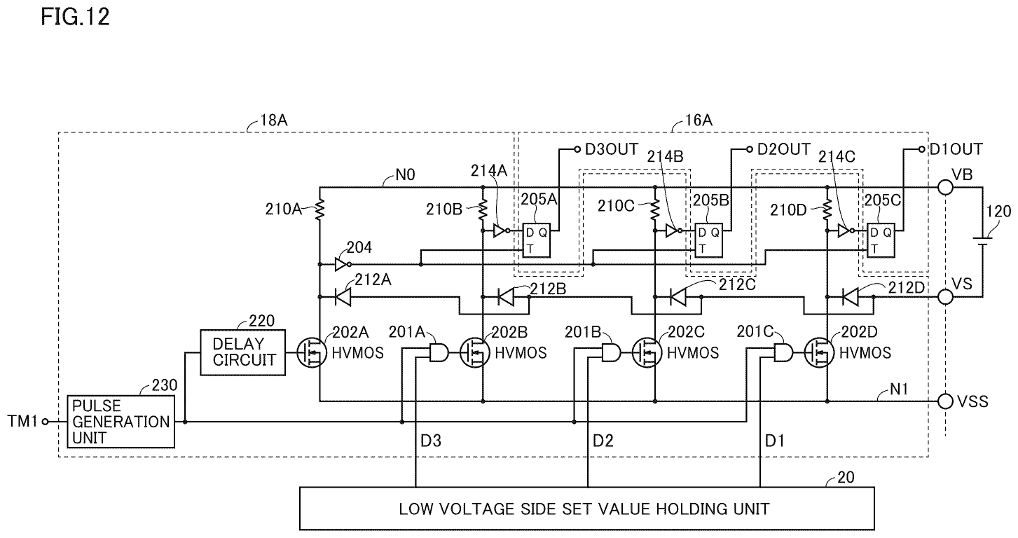

FIG. 12 is a diagram for illustrating a configuration of high voltage side set value holding unit 16A and second level shift unit 18A according to the fourth embodiment. Referring to FIG. 12, high voltage side set value holding unit 16A has a plurality of flip-flops (DT-FFs) 205A to 205C.

Second level shift unit 18A includes pulse generation unit 230, a delay circuit 220, breakdown voltage MOS transistors 202A to 202D, inverters 204 and 214A to 214C, diodes 212A to 212D, resistive elements 210A to 210D, and AND circuits 201A to 201C.

Pulse generation unit 230 is triggered by write signal TM1 to generate and output a one-shot pulse signal. Delay circuit 220 delays the one-shot pulse signal and outputs the delayed one-shot pulse signal to the gate of breakdown voltage MOS transistor 202A.

AND circuit 201A outputs an AND logical operation result based on the one-shot pulse signal generated by pulse generation unit 230 and data D3 held in low voltage side set value holding unit 20 to the gate of breakdown voltage MOS transistor 202B.

Node N0 is connected to terminal VB. Floating power supply 120 is connected between terminal VB and terminal VS. Terminal VSS connected to ground potential GND is connected to node N1. High breakdown voltage MOS transistors 202A and 202B are connected in parallel between node N0 and node N1. Resistive element 210A is provided between the source side of high breakdown voltage MOS transistor 202A and node N0. Resistive element 210B is provided between the source side of high breakdown voltage MOS transistor 202B and node N0. Diode 212A has an anode side connected to terminal VS, which will have an intermediate potential, and a cathode side connected to a connection node between resistive element 210A and high breakdown voltage MOS transistor 202A. Diode 212B has an anode side connected to terminal VS that will have the intermediate potential, and a cathode side connected to a connection node between resistive element 210B and high breakdown voltage MOS transistor 202B.

AND circuit 201B outputs an AND logical operation result based on the one-shot pulse signal generated by pulse generation unit 230 and data D2 held by low voltage side set value holding unit 20 to the gate of breakdown voltage MOS transistor 202C.

High breakdown voltage MOS transistors 202C and 202D are connected in parallel between node N0 and node N1. Resistive element 210C is provided between the source side of high breakdown voltage MOS transistor 202C and node N0.

Resistive element 210D is provided between the source side of high breakdown voltage MOS transistor 202D and node N0. Diode 212C has an anode side connected to terminal VS that will have the intermediate potential, and a cathode side connected to a connection node between resistive element 210C and high breakdown voltage MOS transistor 202C. Diode 212D has an anode side connected to terminal VS that will have the intermediate potential, and a cathode side connected to a connection node between resistive element 210D and high breakdown voltage MOS transistor 202D.

When high breakdown voltage MOS transistor 202C is turned off, the potential of the connection node between resistive element 210C and high breakdown voltage MOS transistor 202C is set to a high potential. Accordingly, inverter 214B outputs a signal set to the “L” level. When high breakdown voltage MOS transistor 202C is driven (or turned on), the potential of the connection node between resistive element 210C and high breakdown voltage MOS transistor 202C falls. Accordingly, inverter 214B outputs a signal set to the “H” level.

When high breakdown voltage MOS transistor 202D is turned off, the potential of the connection node between resistive element 210D and high breakdown voltage MOS transistor 202D is set to a high potential. Accordingly, inverter 214C outputs a signal set to the “L” level. When high breakdown voltage MOS transistor 202D is driven (or turned on), the potential of the connection node between resistive element 210D and high breakdown voltage MOS transistor 202D falls. Accordingly, inverter 214C outputs a signal set to the “H” level.

AND circuit 201C outputs an AND logical operation result based on the one-shot pulse signal generated by pulse generation unit 230 and data D1 held by low voltage side set value holding unit 20 to the gate of breakdown voltage MOS transistor 202D.

High breakdown voltage MOS transistors 202B to 202D are driven based on a one-shot pulse of pulse generation unit 230 and data D3 to D1 held in low voltage side set value holding unit 20. Further, a signal which serves as a trigger for flip-flops 205A to 205C is driven in accordance with a delay signal of delay circuit 220. According thereto, data “1” or “0” is set in flip-flops 205A to 205C based on data D3 to D1.

With this configuration, data D3 to D1 input to second level shift unit 18A are level-shifted to a high potential and held in flip-flops 205A to 205C. Flip-flops 205A to 205C output held data signals from terminals D3OUT to D1OUT.

For the configuration of high voltage side set value holding unit 16A according to the fourth embodiment, four high breakdown voltage MOS transistors can be used. Reducing the number of high breakdown voltage MOS transistors allows a reduced number of components and also allows a simple layout configuration.

Further, while the present example has been described for a 3-bit configuration, it also allows a simplified configuration when it is extended to a larger number of bits.

### Fifth Embodiment

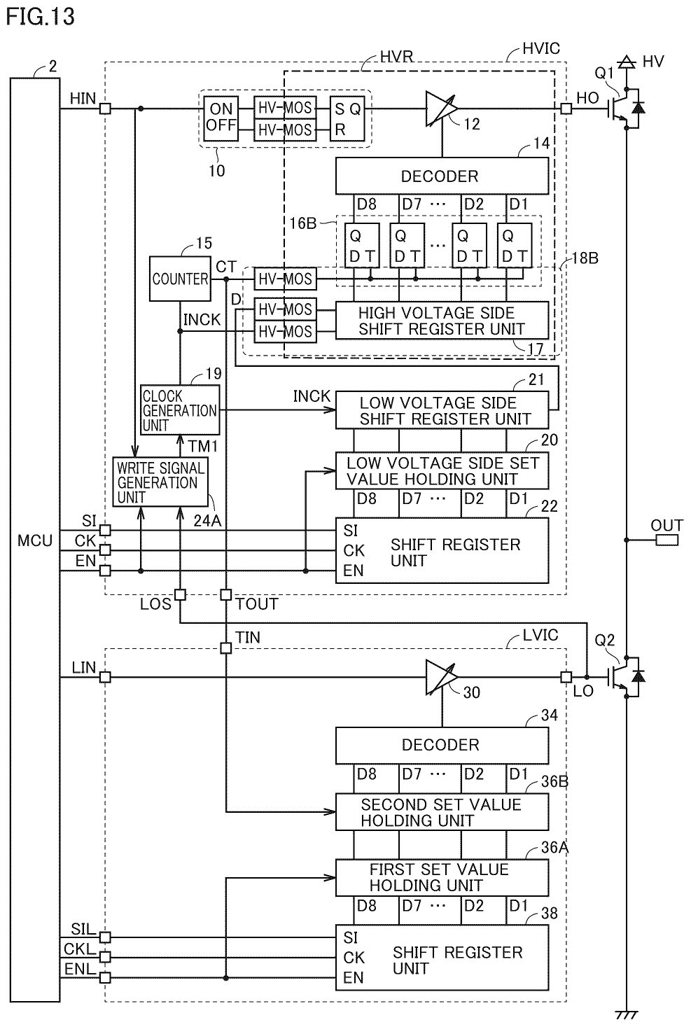

FIG. 13 is a diagram for generally illustrating a configuration of a semiconductor module according to a fifth embodiment. Referring to FIG. 13, the semiconductor module according to the fifth embodiment is different from the semiconductor module according to the fourth embodiment in that second level shift unit 18A and high voltage side set value holding unit 16A are changed in configuration. Specifically, the present embodiment is different in that high voltage side set value holding unit 16A is replaced with a high voltage side set value holding unit 16B and that the number of bits is changed to an 8-bit configuration. 8 DT flip-flops are provided. The present embodiment is different in that second level shift unit 18A is replaced with a second level shift unit 18B. Second level shift unit 18B includes a high voltage side shift register unit 17.

Further, a clock generation unit 19 which generates an internal clock INCK, a low voltage side shift register unit 21 operative in response to internal clock INCK of clock generation unit 19, and a counter 15 are further provided.

Further, the present embodiment is different in that low side output capability variable gate device LVIC is also extended from the 3-bit configuration to the 8-bit configuration. Write signal generation unit 24A outputs write signal TM1 to clock generation unit 19. Clock generation unit 19 generates internal clock INCK in accordance with write signal TM1. Low voltage side shift register unit 21 is operative in response to internal clock INCK to sequentially hold a data signal held in low voltage side set value holding unit 20 and transfer the data signal toward high voltage side shift register unit 17 as a transfer signal D.

High voltage side shift register unit 17 receives a level-converted signal via a high breakdown voltage MOS transistor. Specifically, high voltage side shift register unit 17 is operative in response to internal clock INCK to receive and hold a level-converted signal for transfer signal D. Information held in low voltage side shift register unit 21 is transferred to high voltage side shift register unit 17 in response to internal clock INCK.

Counter 15 counts internal clock INCK, and outputs a control signal CT when a predetermined count is reached.

Specifically, it is necessary to count internal clock INCK 8 times before the information held in low voltage side set value holding unit 20 is all transferred from low voltage side shift register unit 21 to high voltage side shift register unit 17. Counter 15 outputs control signal CT when the counter counts internal clock INCK 8 times. The 8 DT flip-flops of high voltage side set value holding unit 16B hold information of high voltage side shift register unit 17 in response to control signal CT.

Low side output capability variable gate device LVIC has a set value holding unit in a two-stage configuration. Specifically, set value holding unit 36 is replaced with a first set value holding unit 36A and a second set value holding unit 36B.

First set value holding unit 36A is operative in response to an enable signal to hold the information held in shift register unit 38. Second set value holding unit 36B is operative in response to control signal CT to further hold the information held in first set value holding unit 36A.

With this configuration, it is unnecessary to increase the number of high breakdown voltage MOS transistors even when the number of bits is extended, and the number of high breakdown voltage MOS transistors is thus reduced to reduce the number of components and also provide a simplified layout configuration.

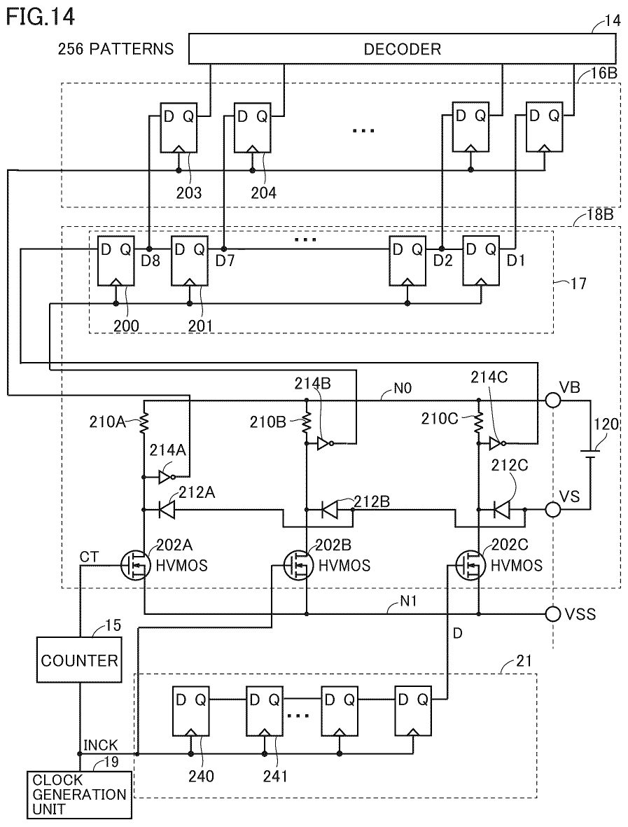

FIG. 14 is a diagram for illustrating a configuration of high voltage side set value holding unit 16B, second level shift unit 18B, and low voltage side shift register unit 21 according to the fifth embodiment. Referring to FIG. 14, high voltage side set value holding unit 16B includes a plurality of flip-flops 203, 204, . . . .

Second level shift unit 18B includes high voltage side shift register unit 17, high breakdown voltage MOS transistors 202A to 202C, diodes 212A to 212C, resistive elements 210A to 210C, and inverters 214A to 214C.

Low voltage side shift register unit 21 includes a plurality of cascaded flip-flops 240, 241, . . . . The plurality of flip-flops 240, 241, . . . each receive internal clock INCK, and sequentially transfer the data held therein to the flip-flop of the subsequent stage. In this example, low voltage side shift register unit 21 has 8 flip-flops, and is operative in response to internal clock INCK to sequentially output the data held therein to high voltage side shift register unit 17 as transfer signal D.

Transfer signal D is input to the gate of high breakdown voltage MOS 202C. Internal clock INCK is input to the gate of high breakdown voltage MOS 202B. Control signal CT of counter 15 is input to the gate of high breakdown voltage MOS 202A. Node N0 is connected to terminal VB. Floating power supply 120 is connected between terminal VB and terminal VS. Terminal VSS connected to ground potential GND is connected to node N1. High breakdown voltage MOS transistors 202A, 202B, and 202C are connected in parallel between the nodes NO and N1. Resistive element 210A is provided between the source side of high breakdown voltage MOS transistor 202A and node N0. Resistive element 210B is provided between the source side of high breakdown voltage MOS transistor 202B and node N0. Resistive element 210C is provided between the source side of high breakdown voltage MOS transistor 202C and node N0. Diode 212A has an anode side connected to terminal VS, which will have an intermediate potential, and a cathode side connected to the connection node between resistive element 210A and high breakdown voltage MOS transistor 202A. Inverter 214A provides an output as a clock input to high voltage side set value holding unit 16B in accordance with a signal at the connection node.

Diode 212B has an anode side connected to terminal VS that will have the intermediate potential, and a cathode side connected to the connection node between resistive element 210B and high breakdown voltage MOS transistor 202B. Inverter 214B provides an output as a clock input to high voltage side shift register unit 17 in accordance with a signal at the connection node. Diode 212C has an anode side connected to terminal VS that will have the intermediate potential, and a cathode side connected to the connection node between resistive element 210C and high breakdown voltage MOS transistor 202C. Inverter 214C provides an output as data input to high voltage side shift register unit 17 in accordance with a signal at the connection node.

With this configuration, data D sequentially transferred from low voltage side shift register unit 21 is level-shifted to a high potential and transferred to high voltage side shift register unit 17.

High voltage side shift register unit 17 is operative in response to internal clock INCK and transfer signal D to sequentially store transfer signal D that is sequentially transferred from low voltage side shift register unit 21 to the 8 flip-flops.

The data held in high voltage side shift register unit 17 is held in high voltage side set value holding unit 16B in response to control signal CT of counter 15.

Further, while the present example is described for an 8-bit configuration, it also allows a simplified configuration when it is extended to a larger number of bits.

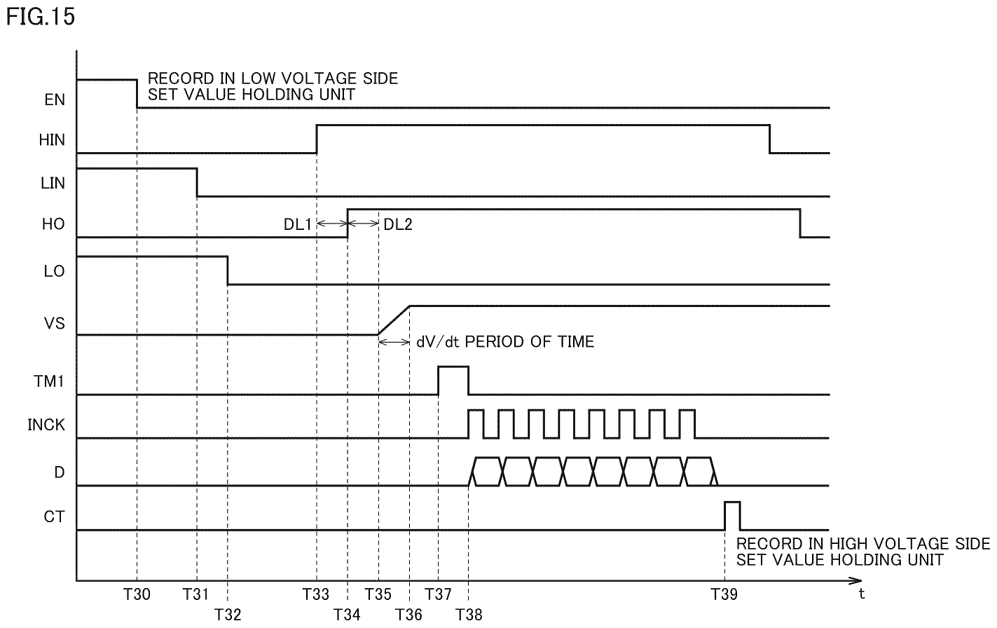

FIG. 15 is timing plots for an output of write signal TM1 according to the fifth embodiment. Referring to FIG. 15, at time T30, when the enable signal falls (or rises), contents recorded in the plurality of flip-flops of shift register unit 22 are extracted and recorded in low voltage side set value holding unit 20, and thereafter at time T31 the low side drive signal of input terminal LIN falls.

At time T32, output terminal LO outputs a gate signal of the “L” level and power transistor Q2 turns off.

At time T33, the high side drive signal of input terminal HIN rises complementarily. At time T34, output terminal HO outputs a gate signal of the “H” level and power transistor Q1 turns on.

Accordingly, for a period of time from time T35 to time T36, the connection node between power transistor Q1 and power transistor Q2 has a rising potential. Accordingly, high voltage region HVR of high side output capability variable gate device HVIC has an abruptly varying voltage for a period of time (i.e., a dV/dt period of time). In this period, signaling cannot be performed in voltage level conversion (or the level shift circuit) and there is a possibility that setting cannot be normally performed.

Accordingly, in the fifth embodiment, write signal generation unit 24 raises write signal TM1 after the period of time having the abrupt variation, or at time T37.

At time T38, clock generation unit 19 outputs internal clock INCK in accordance with write signal TM1 received. Accordingly, low voltage side shift register unit 21 transfers transfer signal D to high voltage side shift register unit 17 in response to internal clock INCK. High voltage side shift register unit 17 sequentially holds transfer signal D in response to internal clock INCK.

Counter 15 counts internal clock INCK, and, at time T39, that is, after the counter counts internal clock INCK 8 times, the counter outputs control signal CT. High voltage side set value holding unit 16B holds the data that is held in high voltage side shift register unit 17 in the flip-flops in response to control signal CT.

Thus, the data signal (D1 to D8) held in low voltage side set value holding unit 20 is held in high voltage side set value holding unit 16 via low voltage side shift register unit 21 and high voltage side shift register unit 17. Decoder 14 converts the data signal into a 256-pattern signal, and thereafter the driving capability of driver 12 is changed.

After the high side drive signal from input terminal HIN rises, write signal generation unit 24 outputs write signal TM1 after delay time DL1 until a gate signal rises from output terminal HO, delay time DL2 until power transistor Q1 is turned on, and the period of time (dV/dt) for which high voltage region HVR varies in voltage as power transistor Q1 is turned on. This allows recording to be done in high voltage side set value holding unit 16B while avoiding a period of time for which voltage level conversion (or the level shift circuit) cannot signal. Write signal generation unit 24 outputs write signal TM1 after a predetermined period of time elapses after the high side drive signal from input terminal HIN rises. The predetermined period of time is set to be longer than a total of delay times DL1 and DL2 and the predetermined period of time (dV/dt) having the variation.

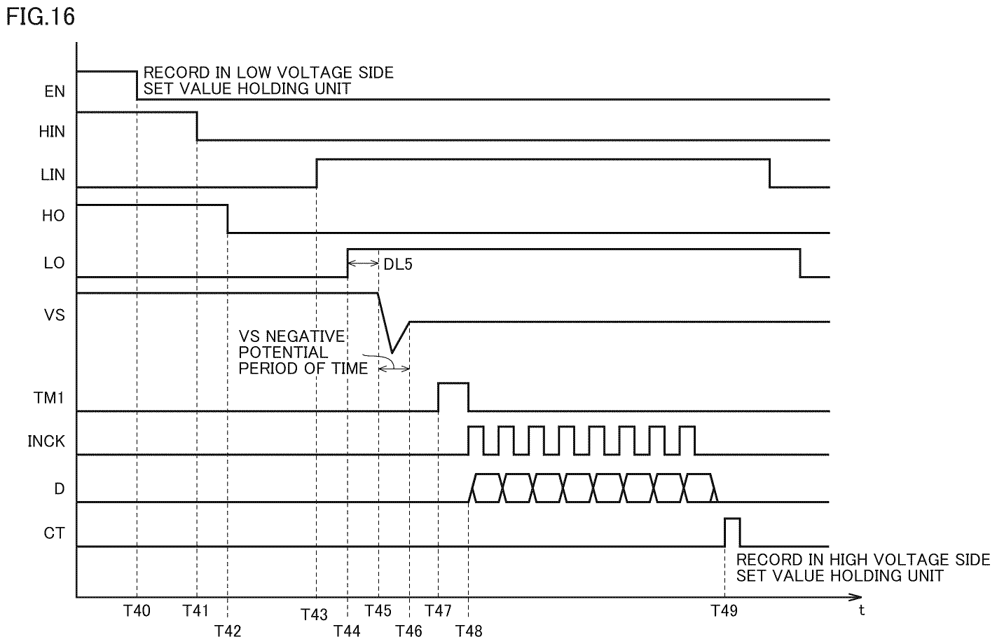

FIG. 16 is other timing plots for the output of write signal TM1 according to the fifth embodiment. Referring to FIG. 16, at time T40, when the enable signal falls (or rises), contents recorded in the plurality of flip-flops of shift register unit 22 are extracted and recorded in low voltage side set value holding unit 20, and thereafter at time T41 the high side drive signal of input terminal HIN falls.

At time T42, output terminal HO outputs a gate signal of the “L” level and power transistor Q1 turns off. At time T43, the low side drive signal of input terminal LIN rises complementarily. At time T44, output terminal LO outputs a gate signal of the “H” level and power transistor Q2 turns on.

Accordingly, for a period of time from time T45 to time T46, the connection node between power transistor Q1 and power transistor Q2 has an abruptly falling potential. Accordingly, high voltage region HVR of high side output capability variable gate device HVIC has an abruptly varying voltage for a period of time (i.e., a VS negative potential period of time). In this period, high voltage region HVR has a negative voltage and therefore, signaling cannot be performed in voltage level conversion (or the level shift circuit), and there is a possibility that setting cannot be normally performed.

Accordingly, in the fifth embodiment, write signal generation unit 24 raises write signal TM1 after the period of time for which high voltage region HVR of high side output capability variable gate device HVIC has a negative voltage, or at time T47.

At time T48, clock generation unit 19 outputs internal clock INCK in accordance with write signal TM1 received. Accordingly, low voltage side shift register unit 21 transfers transfer signal D to high voltage side shift register unit 17 in response to internal clock INCK. High voltage side shift register unit 17 sequentially holds transfer signal D in response to internal clock INCK.

Counter 15 counts internal clock INCK, and, at time T49, that is, after the counter counts internal clock INCK 8 times, the counter outputs control signal CT. High voltage side set value holding unit 16B holds the data that is held in high voltage side shift register unit 17 in the flip-flops in response to control signal CT.

Thus, the data signal (D1 to D8) held in low voltage side set value holding unit 20 is held in high voltage side set value holding unit 16 via low voltage side shift register unit 21 and high voltage side shift register unit 17. Decoder 14 converts the data signal into the 256-pattern signal, and thereafter the driving capability of driver 12 is changed.

Write signal generation unit 24A outputs write signal TM1 after delay time DL5 since the gate signal from output terminal LO rises until power transistor Q2 is turned on and a period of time for which high voltage region HVR has a negative voltage as power transistor Q2 is turned on. This allows recording to be done in high voltage side set value holding unit 16 while avoiding a period of time for which voltage level conversion (or the level shift circuit) cannot signal. Write signal generation unit 24A outputs write signal TM1 after a predetermined period of time elapses after the low side drive signal from input terminal LOS rises. The predetermined period of time is set to be longer than a total of delay time DL5 and the VS negative potential period of time.

With the configuration according to the fifth embodiment, even when the number of bits is extended, the number of high breakdown voltage MOS transistors is reduced to reduce the number of components and also provide a simplified layout configuration.

### Sixth Embodiment

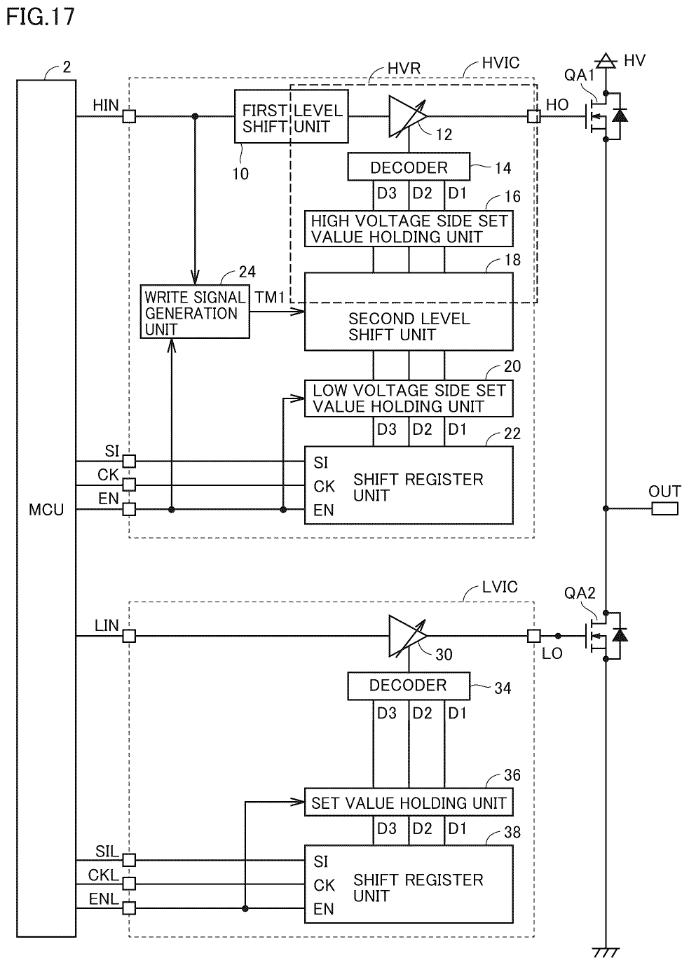

FIG. 17 is a diagram for generally illustrating a configuration of a semiconductor module according to a sixth embodiment. Referring to FIG. 17, the semiconductor module according to the sixth embodiment is different from the semiconductor module according to the first embodiment in that power transistors (or switching elements) Q1 and Q2 are replaced with SiC-MOSFETs QA1 and QA2.

The remainder in configuration is similar. Similar application is possible for SiC-MOSFET. Although a SiC-MOSFET has a large variation in Vth and also has a large individual variation in output characteristics, it is possible to suppress variation as a semiconductor module by adjusting a driver's output capability by the configuration according to the above embodiment. The other embodiments are also similarly applicable.

The embodiments disclosed herein are also intended to be combined within a consistent scope as appropriate and thus implemented. It should be understood that the embodiments disclosed herein have been described for the purpose of illustration only and in a non-restrictive manner in any respect. The scope of the present disclosure is defined by the terms of the claims, rather than the description above, and is intended to include any modifications within the meaning and scope equivalent to the terms of the claims.

What is claimed is:

1. A semiconductor module comprising:
first and second switching elements connected in series between a first potential and a second potential lower than the first potential and operating in a complementary manner;
a high potential side drive circuit including a first driver connected to a first gate of the first switching element and capable of adjusting an output to the first gate; and
a low potential side drive circuit including a second driver connected to a second gate of the second switching element and capable of adjusting an output to the second gate,
the high potential side drive circuit including:
terminals to receive a drive signal, a data signal, a clock signal, and an enable signal, respectively, that are a data communication signal transmitted from an external controller;
a first level shift unit to level-shift the drive signal to a high potential and output the level-shifted drive signal to the first driver;
a first shift register composed of a plurality of cascaded flip-flops, a data signal being recorded in the flip-flops in response to the clock signal and the enable signal, whenever the data signal is recorded in the flip-flops, the data having been recorded in the flip-flops being shifted to adjacent flip-flops;
a low voltage side set value holding unit operative in response to the enable signal to extract and record contents recorded in the plurality of flip-flops of the first shift register;
a write signal generation unit to generate a write signal based on the drive signal and the enable signal;
a second level shift unit operative in response to the write signal to level-shift information held in the low voltage side set value holding unit to a high potential;
a high voltage side set value holding unit connected via the second level shift unit to record information identical to the information recorded in the low voltage side set value holding unit; and
a first decoder to render a current outputting capability of the first driver variable according to the recording of the high voltage side set value holding unit.

2. The semiconductor module according to claim 1, wherein the write signal generation unit activates the write signal after a predetermined period of time elapses in response to the drive signal rising or falling.

3. The semiconductor module according to claim 2, wherein the write signal generation unit receives an output of a drive signal of the low potential side drive circuit and activates the write signal based on the output.

4. The semiconductor module according to claim 1, wherein the low potential side drive circuit includes:
terminals to receive a second drive signal, a second data signal, a second clock signal, and a second enable signal, respectively, that are a data communication signal transmitted from an external controller;
a second shift register composed of a plurality of cascaded flip-flops, a second data signal being recorded in the flip-flops in response to the second clock signal and the second enable signal, whenever the second data signal is recorded in the flip-flops, the data having been recorded in the flip-flops being shifted to adjacent flip-flops;
a first set value holding unit operative in response to the second enable signal to extract and record contents recorded in the plurality of flip-flops of the second shift register;
a second set value holding unit to record information identical to information of the first set value holding unit in response to the write signal; and
a second decoder to render a current outputting capability of the second driver variable according to the recording of the second set value holding unit.

5. The semiconductor module according to claim 1, wherein
the second level shift unit includes:
a pulse generation unit to output the information held in the low voltage side set value holding unit as a one-shot pulse signal in accordance with the write signal; and
a plurality of high breakdown voltage transistors driven in accordance with respective outputs of the pulse generation unit, and
the high voltage side set value holding unit includes a plurality of flip-flop circuits connected to the high breakdown voltage transistors to record the information identical to the information of the low voltage side set value holding unit.

6. The semiconductor module according to claim 1, further comprising a low voltage side shift register composed of a plurality of cascaded flip-flops, a data signal of the low voltage side set value holding unit being recorded in the flip-flops in response to an internal clock signal, whenever the data signal is recorded in the flip-flops, the data having been recorded in the flip-flops being shifted to adjacent flip-flops, wherein
the second level shift unit includes:
a high voltage side shift register composed of a plurality of cascaded flip-flops, a data signal of the low voltage side shift register being recorded in the flip-flops in response to the internal clock signal, whenever the data signal is recorded in the flip-flops, the data having been recorded in the flip-flops being shifted to adjacent flip-flops; and
a plurality of high breakdown voltage transistors disposed between the low voltage side shift register and the high voltage side shift register and driven in accordance with the internal clock signal and the data signal of the low voltage side shift register.

7. The semiconductor module according to claim 1, wherein the first and second switching elements correspond to SiC MOSFETs.
